(19) United States
(12) Patent Application Publication
(10) Pub. No.: US 2021/0284484 A1
(43) Pub. Date: Sep. 16, 2021

(54) Cable Drum for Supplying Energy to an Electrically Powered Utility Vehicle

(71) Applicant: DEERE & COMPANY, Moline, IL (US)

(72) Inventors: ANDRE KLEIN, KAISERSLAUTERN (DE); NICOLAI TARASINSKI, FRANKENTHAL (DE); SIMON PFAFFMANN, MANNHEIM (DE); THORSTEN KOESTERMEYER, HERFORD (DE); MAX KISSEL, KAISERSLAUTERN (DE)

(21) Appl. No.: 17/197,751

(22) Filed: Mar. 10, 2021

(30) Foreign Application Priority Data
Mar. 13, 2020 (DE) 102020203283.1

(51) Int. Cl. B65H 75/44; H02G 11/02; H05K 7/20

(52) U.S. Cl. CPC B65H 75/4478; B65H 75/4468; B65H 2701/34; H05K 7/20009; H02G 11/02

(57) ABSTRACT

A cable drum for supplying energy to an electrically powered utility vehicle, with an axially running winding body which can be set in rotation in order to wind up and unwind an electrical cable, wherein the winding body is formed by a helically wound pipeline with an inlet for the supply of a cooling air stream. To increase the cooling efficiency, the pipeline has a plurality of air outlet openings formed along its wall.

### CROSS REFERENCE TO RELATED APPLICATIONS

This application claims priority under 35 U.S.C. § 119 to German patent application DE 10 2020 203 283.1, filed on 13 Mar. 2020, the disclosure of which is incorporated herein by reference.

### FIELD OF THE DISCLOSURE

The present disclosure generally relates to an optimized cable drum for supplying energy to an electrically powered utility vehicle, and more particularly to a cable drum for supplying energy to an electrically powered utility vehicle with an axially running winding body which can be set in rotation in order to wind up and unwind an electrical cable, wherein the winding body is formed by a helically wound pipeline with an inlet for the supply of a cooling air stream.

### BACKGROUND OF THE DISCLOSURE

DE 850 130 C describes a cable drum for use in electrically driven mobile devices, such as for example excavators or other vehicles. An electrical cable serving for power supply is wound onto and unwound from the cable drum in several layers, depending on whether the device is approaching or moving away from a stationary cable feed point. The cable drum itself comprises a drum casing formed from a snaking hollow pipe which is wound with a clearance and opens into a hollow part of a rotatably mounted cable drum axis. A ventilator presses cooling air through the hollow part of the cable drum axis and then through the snaking pipe, an open end of which is directed into the interior of the cable drum. The air firstly passes through the windings of the snaking pipe and then flows into the interior of the drum. This gives an improved heat dissipation, relative to conventional cable drums, for the cable layers wound onto the drum casing, which heat up to a greater or lesser extent depending on the power loss.

It is an object of the present disclosure to further improve a cable drum of the type cited initially with respect to its cooling efficiency. This object is achieved by means of a cable drum having the features of claim 1.

### SUMMARY OF THE DISCLOSURE

The cable drum for supplying energy to an electrically powered utility vehicle comprises an axially running winding body which can be set in rotation in order to wind up and unwind an electrical cable, wherein the winding body is formed by a helically wound pipeline with an inlet for the supply of a cooling air stream. According to this disclosure, to increase the cooling efficiency, the pipeline comprises a plurality of air outlet openings formed along its wall. These allow a forced cooling air feed onto a cable portion wound onto the winding body. The air outlet openings may here be evenly distributed over the entire length of the wound pipeline in the region of the winding body, so as to guarantee homogenous cooling of a cable portion wound thereon. The risk of undesirable local heat spots within superposed cable layers is thus decisively reduced. Since the air outlet openings can be made in the wall of the pipeline with no additional space requirement, also a particularly compact construction is ensured.

For the air feed, the pipeline is usually connected to a compressed air source which is part of an electrically powered utility vehicle equipped with the cable drum. The compressed air may also flow through an expansion valve in order to lower its temperature before entering the pipeline. The cooling effect can thus be further increased.

The electrically powered utility vehicle may be an agricultural, forestry or construction machine which performs an associated work process on a defined area. Merely as an example, this could be plowing a field by means of an agricultural tractor, a harvesting process performed by means of a combine harvester or wood harvester, dredging work by means of a shovel loader in a gravel pit, and similar.

Further advantageous refinements of the cable drum according to the disclosure arise from the subclaims.

Preferably, the air outlet openings are directed radially outward in the direction of a cable portion wound onto the winding body, so that the cooling air emerging from the air outlet openings hits this directly. Here, the cooling air passes through the region of gaps formed between the cable layers, where it dissipates the accumulated lost heat into the external environment. The air outlet openings are typically formed as round and/or slotted openings.

To ensure as even a cooling as possible, it is furthermore possible for the air outlet openings to be oriented alternately along the wall at different angles between 0 and 45 degrees relative to a radial plane spanned by the winding body, in order to achieve a diffuse cooling air stream.

The pipeline may be made of metal and/or plastic. Inter alia, it is conceivable to use a plastic casing pipe to protect the wound cable, wherein this has a supportive metal core.

To ensure an air passage between the cable layers that is as unhindered as possible, it is advantageous if the spacing of the individual windings of the pipeline is greater than the outer diameter of the cable.

The same effect arises for the case where the diameter of the pipeline is greater than the outer diameter of the cable. Here, a distance between the windings of the respective cable layer is set which corresponds to the size difference.

The cable drum according to the disclosure for supplying energy to an electrically powered utility vehicle is explained in more detail below with reference to the attached drawings. Corresponding components or those with comparable function carry the same reference signs.

Other features and aspects will become apparent by consideration of the detailed description and accompanying drawings.

### BRIEF DESCRIPTION OF THE DRAWINGS

FIG. 1 is a perspective view of an exemplary embodiment of the cable drum according to the invention.

FIG. 2 is a sectional depiction of the cable drum shown in FIG. 1.

Before any embodiments are explained in detail, it is to be understood that the disclosure is not limited in its application to the details of construction and the arrangement of components set forth in the following description or illustrated in the following drawings. The disclosure is capable of other embodiments and of being practiced or of being carried out in various ways. Further embodiments of the invention may include any combination of features from one or more dependent claims, and such features may be incorporated, collectively or separately, into any independent claim.

### DETAILED DESCRIPTION

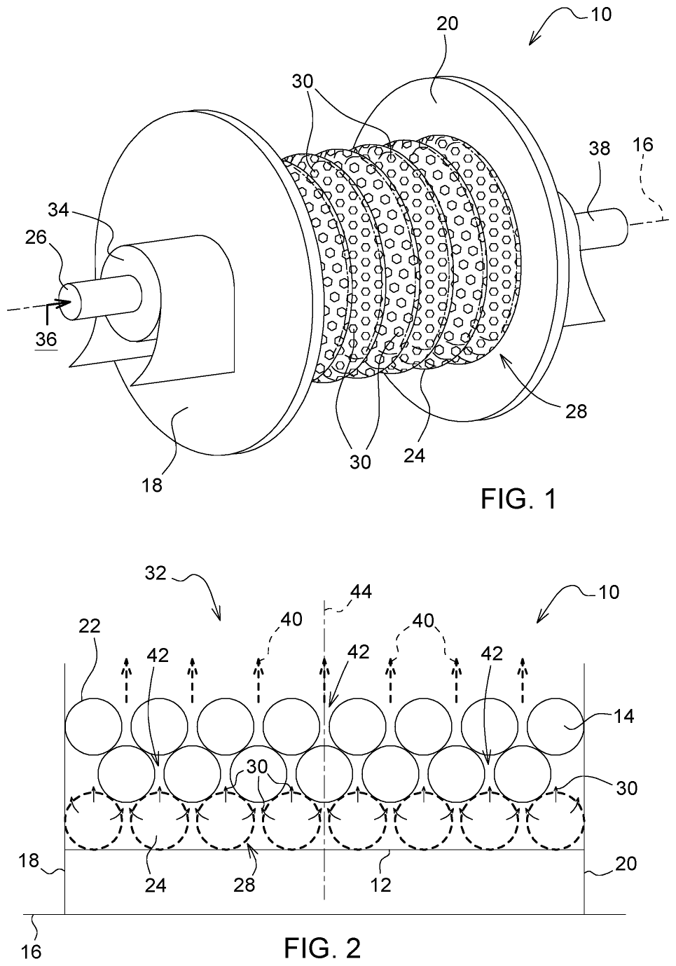

FIG. 1 shows a perspective view of an exemplary embodiment of the cable drum according to this disclosure for supplying energy to an electrically powered utility vehicle. In particular, the cable drum is part of an arrangement as described in DE 10 2018 212 150 A1 for the case of a utility vehicle configured as a field chopper.

The cable drum 10 comprises an axially running winding body 12 which can be set in rotation about a rotational axis 16 in order to wind up and unwind an electrical cable 14 shown in FIG. 2. For this, the winding body 12 is connected to an electric motor drive (not shown) of the utility vehicle. Left and right terminating flanges 18, 20 form the axial limit of the winding body 12.

The cable 14 serves primarily to supply power to the utility vehicle and comprises a plurality of individual cores consisting of copper, which run mutually insulated in a protective outer sheathing 22. In addition, the cable 14 may serve for electrical and/or optical data transmission. In such a case, the cable 14 comprises further cores in the form of corresponding data and/or control lines. Optical data transmission takes place by means of plastic-sheathed waveguides.

As evident from FIG. 1, the cooling body 12 is formed by a helically wound pipeline 24 with an inlet 26 for the supply of a cooling air stream. The pipeline 24 has a plurality of air outlet openings 30 formed along its wall 28. These allow a forced cooling air feed onto a cable portion 32 wound onto the winding body 12. The air outlet openings 30 are evenly distributed over the entire length of the wound pipeline 24 in the region of the winding body 12. For example, the air outlet openings 30 are formed as round and/or slotted openings.

The pipeline 24 is connected via a rotary passage 34 to a compressed air source 36 which is part of the utility vehicle. According to an optional refinement, the compressed air also passes through an expansion valve in order to lower its temperature before entry into the pipeline 24.

The air supply from the compressed air source 36 is here adapted according to the degree of winding of the cable drum 10. Thus the amount of waste heat to be dissipated naturally diminishes with a decreasing number of superposed cable layers. The cable length unwound or that remaining on the winding body 12 may for example be determined by means of a rotary encoder 38 connected to the rotational axis 16. For this, the number of revolutions detected by the rotational encoder 38 and the direction of rotation of the winding body 12 are evaluated. In addition, the electrical power transmitted via the cable 14 is taken into account on the basis of measurement of current intensity by sensors. The amount of air supplied is reduced with a decreasing number of cable layers or diminishing current intensity.

According to the sectional depiction of FIG. 2, the air outlet openings 30 are directed radially outward in the direction of a cable portion 32 wound onto the winding body 12, so that the cooling air 40 emerging from the air outlet openings 30 hits this directly. Here, the cooling air 40 passes through the region of gaps 42 formed between the cable layers, where it dissipates the accumulated lost heat into the external environment. To ensure as even a cooling as possible, it is furthermore possible for the air outlet openings 30 to be oriented alternately along the wall 28 at different angles between 0 and 45 degrees relative to a radial plane 44 spanned by the winding body 12, in order to achieve a diffuse cooling air stream.

The pipeline 24 is made of metal and/or plastic. Inter alia, it is conceivable to use a plastic casing pipe to protect the wound cable 14, wherein this has a supportive metal core.

To ensure an air passage between the cable layers that is as unhindered as possible, in FIG. 2, the spacing of the individual windings of the pipeline 24 is greater than the outer diameter of the cable 14.

The same effect arises for the case not shown in FIG. 2, where the diameter of the pipeline 24 is greater than the outer diameter of the cable 14. Here, a distance between the windings of the respective cable layer is set which corresponds to the size difference.

Various features are set forth in the following claims.

What is claimed is:

1. A cable drum for supplying energy to an electrically powered utility vehicle, with an axially running winding body which can be set in rotation in order to wind up and unwind a cable, wherein the winding body is formed by a helically wound pipeline with an inlet for the supply of a cooling air stream, wherein the pipeline has a plurality of air outlet openings formed along its wall.

2. The cable drum as claimed in claim 1, wherein the air outlet openings are directed radially outward in the direction of a cable portion wound onto the winding body.

3. The cable drum as claimed in claim 2, wherein the air outlet openings are oriented alternately along the wall at different angles between 0 and 45 degrees relative to a radial plane spanned by the winding body.

4. The cable drum as claimed in claim 1, wherein the pipeline is made of metal or plastic.

5. The cable drum as claimed in claim 1, wherein a spacing of the individual windings of the pipeline is greater than the outer diameter of the cable.

6. The cable drum as claimed in claim 1, wherein the diameter of the pipeline is greater than the outer diameter of the cable.
